(19) United States
(12) Patent Application Publication
(10) Pub. No.: US 2026/0293050 A1
(43) Pub. Date: Sep. 24, 2026

(54) TWO-PHASE IMMERSION COOLING FOR ELECTRONIC DEVICES

(71) Applicant: ROSSEAU GROUP INTERNATIONAL INC., Markham (CA)

(72) Inventor: Richard MARGERISON, Georgetown, TX (US)

(21) Appl. No.: 19/475,848

(22) PCT Filed: Apr. 16, 2024
(86) PCT No.: PCT/CA2024/050490

§ 371 Date: Oct. 16, 2025

Related U.S. Application Data
(60) Provisional application No. 63/459,920, filed on Apr. 17, 2023.

(51) Int. Cl. H05K 7/20; H05K 7/14

(52) U.S. Cl. CPC H05K 7/203; H05K 7/1415; H05K 7/20136; H05K 7/20327; H05K 7/20409

(57) ABSTRACT

There is provided an immersion cooling system for electronic devices. The system may include a tank which can store a cooling liquid. Electronic devices within the tank can cause cooling liquid to evaporate, which vapor is then transported to a cooling unit via vapor outlet. The cooling unit may include a vapor input, one or more tubes in fluid communication with the vapor input, and one or more fans blowing air towards the tubes. The cooling vapor may condense to liquid form, and be directed to a condensation return channel. The pressure at the vapor outlet of the tank may be substantially equal to the pressure within the tubes.

### CROSS-REFERENCE TO RELATED APPLICATIONS

This claims the benefit of U.S. Provisional Application Nos. 63/459,920 and 63/539,268, filed Apr. 17, 2023 and Sep. 19, 2023, respectively, the entire contents of which are both incorporated herein by reference.

### FIELD

This disclosure relates to immersion cooling of electronic devices.

### BACKGROUND

As electronic devices (e.g., computing devices such as servers, cryptocurrency miners, etc., as well as networking devices and devices connected thereto) function, some of the electricity drawn thereby is converted into heat, which tends to increase the temperature of the devices over time. In absence of suitable cooling, the devices may heat up to temperatures outside of desired operating ranges, thus rendering them to less efficient operation, shutdown, malfunction or even damage. Various cooling approaches may be used to actively keep the electronic devices from overheating.

For instance, using immersion cooling, electronic devices are submerged in a tank filled with a liquid that is thermally-conductive yet electrically non-conductive. Some cooling liquids (e.g. 3M Novec Fluids) have a boiling point which is relatively low (e.g. 50 degrees Celsius). In two-phase immersion cooling systems, the cooling liquid may come into direct contact with hot components and undergo an evaporation process to cool the hot components and transfer heat out of the liquid. The resulting vapour may then be cooled by a heat exchanging method such as a condenser coil within the tank, which results in the vapour returning to the liquid form (i.e. condensing) and recirculating into the tank.

However, when implemented in data centers or other high-density computing facilities, typical two-phase immersion cooling systems present efficiency and operational challenges, as servicing, together with the addition, removal and/or reconfiguring of computers inside a given tank frequently occurs.

### SUMMARY

According to an aspect, there is provided an immersion cooling system for electronic devices, the system comprising: a tank including: a front portion having an opening for receiving a cooling liquid; a rear portion in fluid communication with said front portion; a lip extending downward from an upper surface of said front portion into said tank; one or more housings, each of said housings containing an electronic device to be immersed in the cooling liquid, each of the housings including: a front face having a top end at a first height; first and second sidewalls extending from said front face; a top surface having a second height higher than said first height and extending from said first sidewall to said second sidewall; a top wall protruding from said top surface and extending from said first sidewall to said second sidewall; and an interface between said top surface and said top wall, said interface forming a seal with said lip of said tank to prevent movement of evaporated cooling liquid from said rear portion to said front portion.

According to another aspect, there is provided a housing for an electronic device in an immersion cooling tank, the housing comprising: a front face having a top end at a first height; first and second sidewalls extending from said front face; a top surface having a second height higher than said first height and extending from said first sidewall to said second sidewall; an upper face connecting said top surface to said front face, said upper face extending from said first sidewall to said second sidewall; a top wall protruding from said top surface and extending from said first sidewall to said second sidewall; and an interface between said top surface and said top wall, said interface being configured to form a seal with a lip of said immersion cooling tank to prevent movement of evaporated cooling fluid from entering an area between said lip and said top wall.

According to a further aspect, there is provided a tank for immersion cooling of electronic devices contained in a housing, the tank comprising: a front wall and a rear wall connected by first and second side walls; a front portion having an opening for receiving a cooling liquid; a rear portion in fluid communication with said front portion; a lip extending downward from an upper surface of said front portion into said tank, said lip configured to form a seal with said housing; wherein the cooling liquid evaporates and travels to the rear portion, and wherein the electronic devices are immersable in said cooling liquid.

According to a yet further aspect, there is provided an immersion cooling system for electronic devices, the system comprising: a tank as described herein, and a housing as described herein, wherein the housing and tank are arranged such that the lip of the tank forms a seal with the top wall of the housing.

According to still another aspect, there is provided an immersion cooling system for electronic devices, the system comprising: a tank for receiving a cooling liquid, said tank comprising a vapor outlet and a condensation inlet; one or more housings, each of said housings containing an electronic de vices to be immersed in the cooling liquid, wherein said housing configured to direct evaporated cooling liquid is directed to said vapor outlet; and a cooling unit comprising: a vapor input configured to receive said evaporated cooling liquid; one or more tubes in fluid communication with said vapor input, said evaporated cooling liquid configured to circulate through said one or more tubes; one or more fans configured to blow air towards said one or more tubes; a condensation return channel fluidly coupled to said condensation inlet, said condensation return channel configured to receive a condensed cooling liquid, wherein a pressure at said vapor outlet of said tank is substantially equal to a pressure within said one or more tubes.

According to still another aspect, there is provided a cooling system for immersion cooling of electronic devices contained in a housing and stored in a tank, the cooling system comprising: a vapor input configured to receive evaporated cooling liquid from said housing; one or more tubes in fluid communication with said vapor input, said evaporated cooling liquid configured to circulate through said one or more tubes; one or more fans configured to blow air towards said one or more tubes; a condensation return channel configured to receive condensed cooling liquid and to dispense said condensed cooling to said tank; wherein a pressure within said tank is substantially equal to a pressure within said one or more tubes.

Other features will become apparent from the drawings in conjunction with the following description.

### BRIEF DESCRIPTION OF DRAWINGS

In the figures which illustrate example embodiments,

FIG. 1A is a perspective view of an example tank for immersion cooling of electronic devices, in accordance with an embodiment;

FIG. 1B is a top view of the tank of FIG. 1A;

FIG. 2A is a front elevation view of the tank of FIG. 1A;

FIG. 2B is a rear elevation view of the tank of FIG. 1A;

FIG. 3 is a side elevation view of the tank of FIG. 1A when filled with cooling liquid;

FIG. 4 is a cut-away side elevation view of the tank of FIG. 1A having a housing placed therein;

FIG. 5A is a perspective view of the tank of FIG. 1A with the lid removed;

FIG. 5B is a top view of the tank depicted in FIG. 5A;

FIG. 6A is a perspective view of a front-facing side of a housing;

FIG. 6B is a perspective view of a rear-facing side of the housing depicted in FIG. 6A;

FIG. 7A is a perspective view of an underside of the housing depicted in FIG. 6A;

FIG. 7B is a side elevation view of the housing depicted in FIG. 6A; and;

FIG. 8 is a perspective view of an immersion cooling system, in accordance with an embodiment;

FIG. 9 is a cutaway perspective view of a rear side of an immersion cooling system, in accordance with some embodiments;

FIG. 10A depicts a perspective view of an example cooling system which includes a heat exchange system coupled to inlet and outlet ports;

FIG. 10B is a perspective view facing an underside of an example conduit, in accordance with some embodiments;

FIG. 11A is a simplified perspective view of an example cooling unit;

FIG. 11B is a perspective view of the example cooling unit of FIG. 11A;

FIG. 11C is a rear perspective view of the example cooling unit of FIG. 11A with paneling removed;

FIG. 11D is a side perspective view of cooling unit facing towards a side;

FIG. 11E is a rear view of an example cooling unit, in accordance with some embodiments;

FIG. 11F is a perspective view of an example cooling unit which includes a bypass from a collection basin to a conduit channel;

FIG. 12A depicts still another example embodiment of a heat exchange system, in accordance with some embodiments;

FIG. 12B is a depiction of an interior of the system shown in FIG. 12A;

FIG. 12C is a depiction of an interior of the system of FIG. 12A with a side wall omitted for ease of reference;

FIG. 13A depicts a perspective view of still another example immersion cooling system, in accordance with some embodiments;

FIG. 13B is a side view of the system depicted in FIG. 13A;

FIG. 13C is a top view of the system depicted in FIG. 13A;

FIG. 13D is a rear view of the system depicted in FIG. 13A, with the panels of the cooling unit removed for simplicity;

FIG. 13E depicts the system of FIG. 13A with the casing of the tank removed; and

FIG. 13F is an illustration of an example immersion cooling system having a rectangular-shaped cooling unit, in accordance with some embodiments.

These drawings depict example embodiments for illustrative purposes, and variations, alternative configurations, alternative components and modifications may be made to these example embodiments.

### DETAILED DESCRIPTION

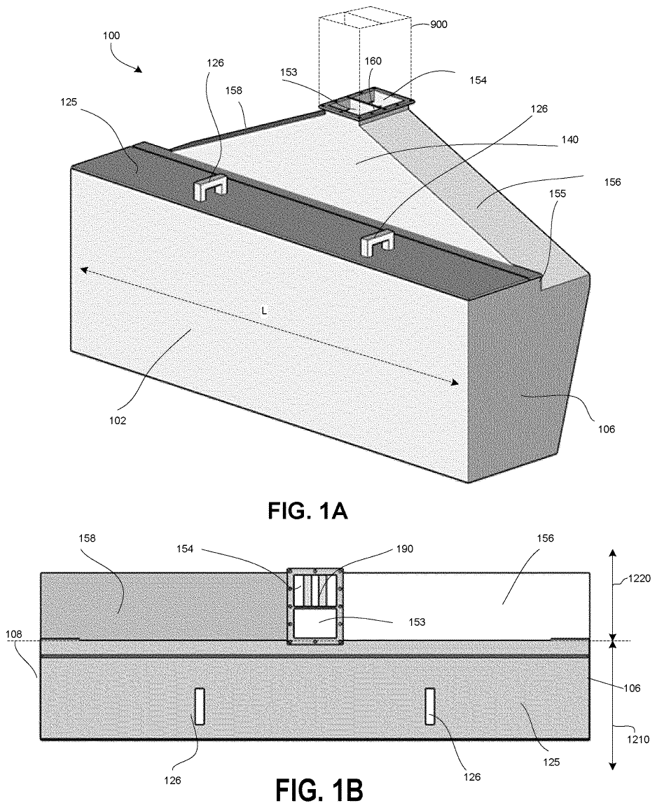

FIG. 1A depicts an example tank 100 of a two-phase immersion cooling system for electronic devices, in accordance with an embodiment.

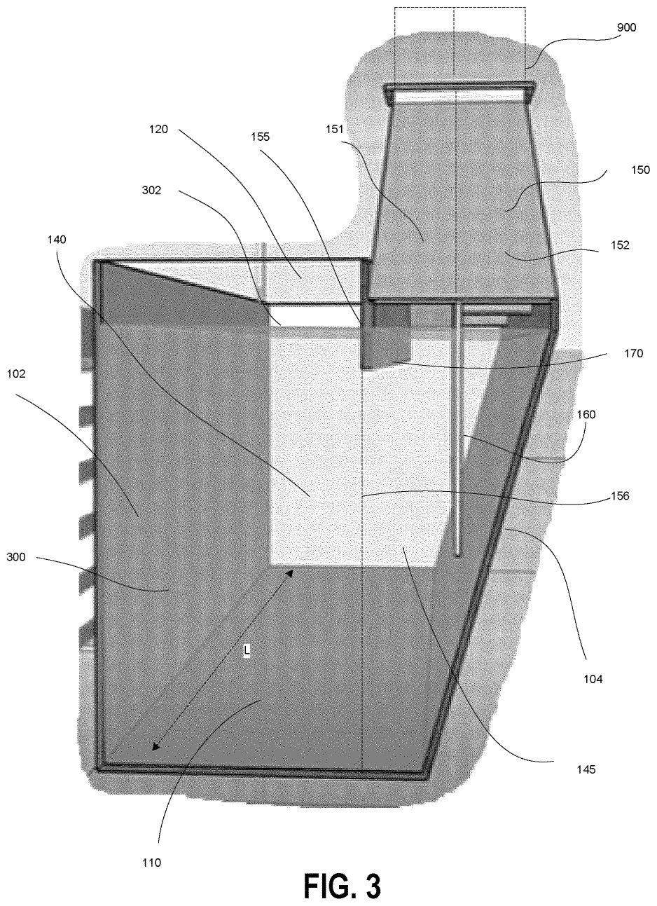

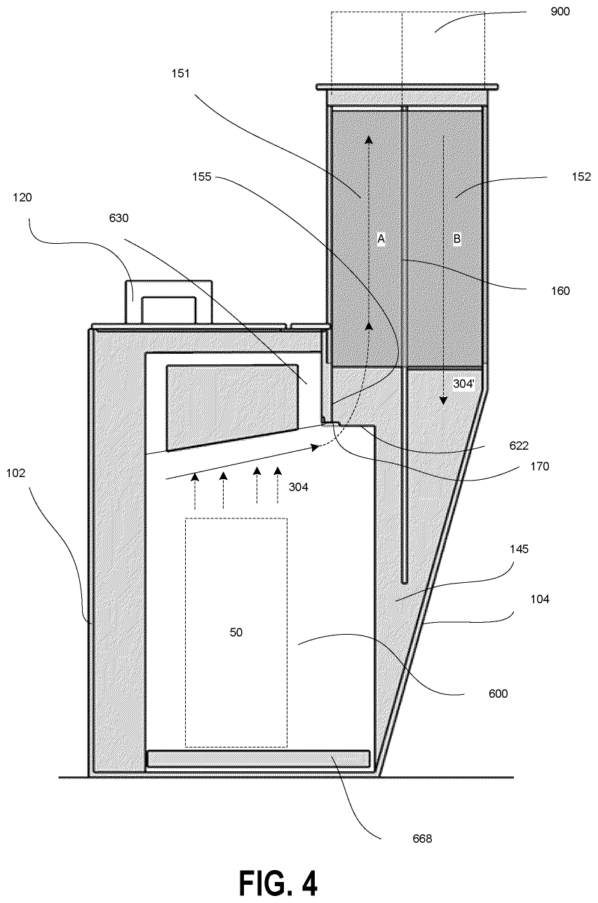

Tank 100 includes front wall 102 and rear wall 104 extending along a longitudinal axis of tank 100. Front and rear walls 102, 104 are terminated at one end by a side wall 106, and at an opposite end by a side wall 108. As depicted, side walls 106 and 108 are substantially parallel to one another, although other sidewall orientations are contemplated. Together, side walls 106 and 108 and front and rear walls 102 and 104, and floor 110 define a liquid-sealed container to contain a cooling liquid 300 (FIG. 3) and receive one or more electronic devices 50 stored in housings 600 (FIG. 4) which may be immersed in the cooling liquid 300.

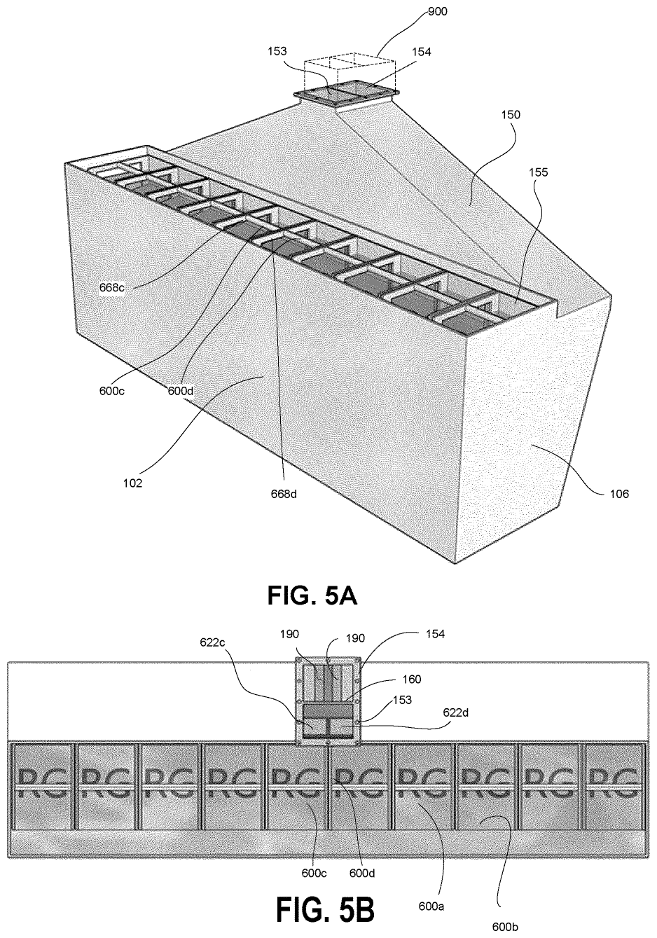

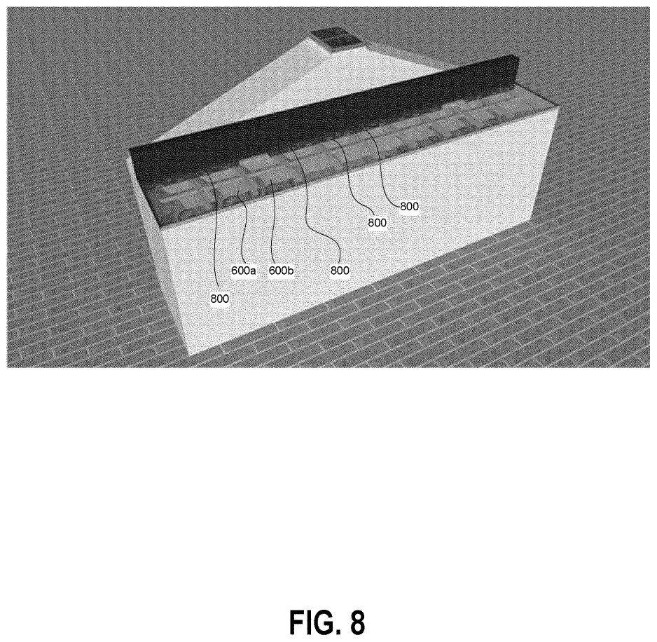

In the embodiments depicted in FIGS. 1A and 5A, tank 100 has an opening 120 to permit access to the reservoir within tank 100, allowing for convenient addition and removal of housings 600 containing electronic devices 50. In some embodiments, opening 120 may be covered by a lid 125 or suitable cover, e.g., to provide protection of tank contents from debris and other unwanted elements. In some embodiments, lid 125 may be a removable lid. As depicted, lid 125 may include one or more handles 126 or grips for facilitating the removal and replacement of lid 125. In some embodiments, such that which is depicted in FIG. 8, lid 125 may be in a hinged configuration in which one end of lid 125 may be rotated about an axis so as to gain access to opening 120.

As depicted particularly in FIG. 3, tank 100 includes a lip 155 which may be a barrier which extends downward from a top surface of opening 120. In some embodiments, as shown in FIG. 3, lip 155 extends downward to an extent that lower end 170 of lip 155 is below the cooling liquid level 302 in tank 100.

In some embodiments, as depicted particularly in FIG. 3, the interior space of tank 100 is subdivided into a front portion 140, a rear portion 145, and upper tank portion 150. In some embodiments, lip 155 extends downward from a top surface of opening 120 for part of the height of the front wall 102 to generally define a boundary 156 between the front portion 140 and the rear portion 145 which extends along an axis 156 projecting downward from lip 155. Upper tank portion 150 is a portion of tank 100 which is defined by the space vertically above the rear portion 145 and behind lip 155.

In some embodiments, a barrier 160 extends longitudinally across upper portion 150 to subdivide upper portion 150 into a vapor zone 151 and a condensation return zone 152. In some embodiments, vapor zone 151 culminates in vapor outlet 153 at the top vertical end of upper portion 150. In some embodiments, condensation return zone culminates in condensation inlet 154 at the top vertical end of upper portion 150.

In some embodiments, barrier 160 creates an impermeable barrier between vapor-containing spaces (e.g. vapor zone 151 and vapor outlet 153), and condensation-containing spaces (e.g. condensation return zone 152 and condensation inlet 154), such that gases present in zone 151 cannot mix with liquids present in zone 152. In some embodiments, barrier 160 extends generally longitudinally across from upper sidewall 156 to upper sidewall 158. In some embodiments, barrier 160 may further extend downward into rear portion 145. In some embodiments, barrier 160 does not extend so far downward as to make contact with rear wall 104 of tank 100. In some embodiments, barrier 160 may make contact with rear wall 104, provided such contact does not result in a fluid-tight seal, such that cooling liquid 300 may still flow past barrier 160.

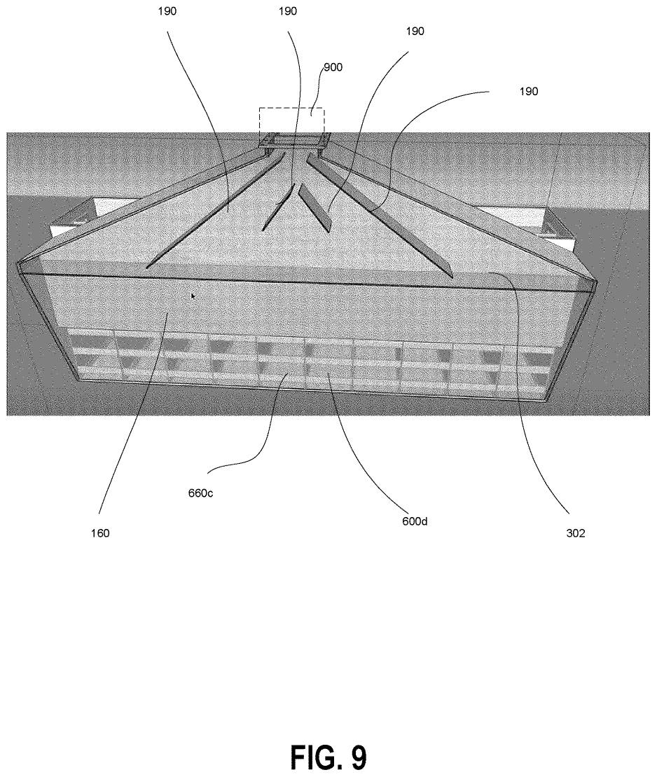

As depicted in FIGS. 1B and 9, in some embodiments, condensation return zone 152 may include one or more panels 190. Panels 190 may facilitate the dispersion of condensed cooling liquid 304′ along length L of tank 100 when returning to tank 100 via condensation return zone 152. Although FIG. 9 depicts 4 panels 190, it is contemplated that in other embodiments, fewer than 4 or more than 4 panels 190 may be present. In some embodiments, tank 100 might not include any panels 190 and condensed cooling liquid 304′ may circulate in cooling liquid 300 via convection currents.

As depicted in FIG. 3, cooling liquid 300 may be dispensed into tank 100 and at least partially fills the front portion 140 and rear portion 145 of tank 100. When cooling liquid is present, a fluid level 302 (also referred to herein as fill line 302) may define the upper vertical limit of the depth of the cooling liquid 300.

During operation, electronic devices 50 within one or more housings 600 may be placed within tank 100, thereby immersing said devices 50 in cooling liquid 300, as depicted in FIGS. 4, 5A and 5B. Heat generated by electronic devices 50 may cause cooling liquid 300 to evaporate, generating cooling liquid vapor 304. As described below, housing 600 is configured to direct cooling liquid vapor 304 into rear portion 145, resulting in the cooling liquid vapor 304 travelling through cooling liquid 300 and up into vapor zone 151, and eventually through vapor outlet 153 (depicted as path A in FIG. 4).

Upon reaching vapor outlet 153, cooling liquid vapor may be treated by a downstream heat exchange system 900 which may, for example, remove heat from cooling liquid vapor. For example, a downstream heat exchange system 900 may cause cooling liquid vapor 304 to cool and condense back into liquid form 304′. Condensed cooling liquid 304′ may then be routed to re-enter tank 100 via condensation inlet 154, where gravity will cause the condensed cooling liquid 304′ to fall down through condensation return zone 152 and between barrier 160 and rear wall 104. In some embodiments, condensed cooling liquid 304′ may be lower in temperature than the average temperature of the cooling liquid 300, and therefore may continue to sink past the lower end of barrier 160 via convection currents, resulting in re-circulation.

As depicted in FIG. 4, one or more electronic devices 50 are placed within one or more housings 600. Each housing 600 is configured to rest on tank floor 110 and may be slid or otherwise translated horizontally within tank 100. In some embodiments, housing 600 may incorporate a hanger system configured to suspend electronic devices 50 and/or housings 600 above floor 110 of tank 100, as described, for example, in U.S. Provisional Patent Application No. 63/435,942, filed on Dec. 29, 2022, the entire contents of which are incorporated herein by reference. When housing 600 is in an operating configuration, an electronic device 50 contained therein is immersed in cooling liquid 300. In some embodiments, tank 100 may contain a single housing 600 containing a single electronic device 50. In some embodiments, tank 100 may contain a single housing 600 containing a plurality of electronic devices 50. In some embodiments, tank 100 may contain a plurality of housings 600, each containing one or more electronic devices 50.

As shown in FIG. 4, a housing 600 may be pressed against lip 155 of tank 100 at a desired horizontal position along length L of tank 100. This horizontal position may be adjusted by sliding housing 600 along the floor 110 of tank 100 or by lifting and repositioning housing 600 within tank 100. Conveniently, this horizontal position may be dynamically adjusted during operation of electronic devices 50. Since housing 600 rests on the floor 110 of tank 100, there is no need to unfasten any fasteners to change the horizontal position of a mounted electronic device 50.

The horizontal positions of electronic devices 50 along length L may allow for housings 600 to be packed tightly together (as depicted in FIGS. 5A, 5B and 8), or to be spaced apart as desired. Horizontal spacing may be selected, for example, based on an amount of heat generated by each electronic device 50, the number of electronic devices 50 to be accommodated in tank 100, the need to avoid interference (e.g., radiofrequency interference) between electronic devices 50, or other criteria.

In some embodiments, the horizontal size (i.e., width) of each housing 600 may vary, to accommodate electronic devices 50 of various sizes, without constraints beyond the height of the top wall 630 of the housing 600 forming a seal with lip 155 of the tank 100.

During operation, cooling liquid 300 is dispensed into the bottom of tank 100 (e.g. via opening 120) at an initially cooler temperature. As electronic devices 50 operate, cooling liquid 300 in contact with electronic devices 50 whose surfaces may exceed the boiling point of cooling liquid 300, causing cooling liquid 300 to evaporate to form cooling liquid vapor 304. As cooling liquid evaporates, heat is transferred away from the electronic devices 50 and the cooling liquid vapor 304 flows upward towards the vapor zone 151.

In accordance with the principles of convection, a temperature gradient may be formed whereby relatively cooler temperatures of cooling liquid 300 are at the bottom of tank 100 and relatively warmer temperatures are near the fill line 302 of tank 100. In some embodiments, the vertical position of a given electronic device 50 within housing 600 may be selected to be placed along this gradient based on an optimal working temperature range of that electronic device 50. For example, in some embodiments, the temperature gradient in tank 100 may range from approximately 20° C. and 80° C., where the lower range is the temperature of cooling liquid 300 when dispensed into tank 100. In some embodiments, the temperature gradient in tank 100 may range from approximately 30° C. to 62° C., again where the lower range is the temperature of cooling liquid 300 when dispensed into tank 100.

As shown in FIG. 4, upper face 612 of housing 600 slopes upward towards rear wall 104. This slope facilitates the flow of cooling liquid vapor 304 bubbles towards rear portion 145 of tank 100. In some embodiments, the angle the slope of upper face 612 may be any angle greater than 0 degrees to the horizontal. In general, a greater angle to the horizontal will facilitate faster and/or easier movement of vapour 304 bubbles. In some embodiments, a upper face 612 may be horizontal, as the vapour pressure may build up and nevertheless result in vapour 304 migrating to outlet 622 without a slope in upper face 612.

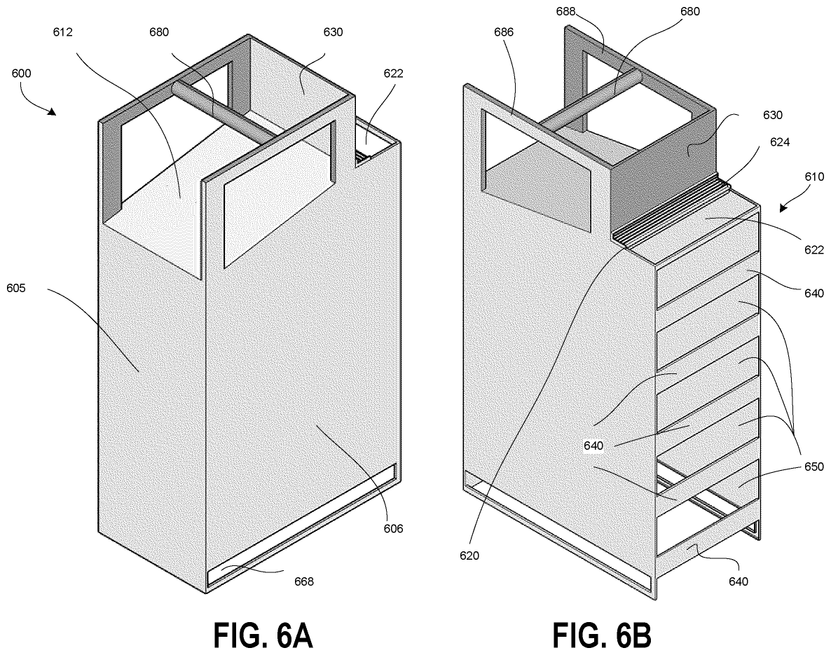

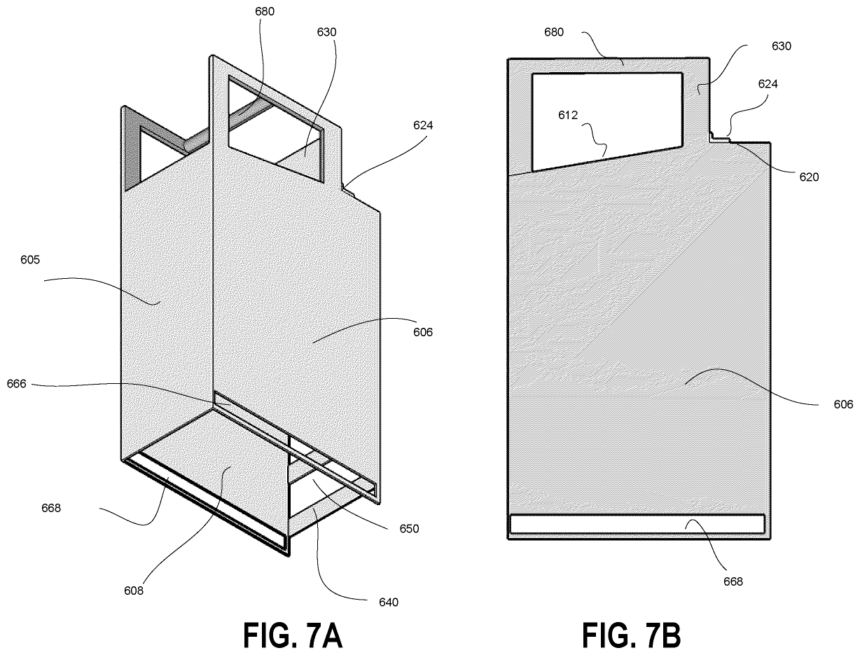

FIGS. 6A, 6B, 7A and 7B each depicts a housing 600, in accordance with an embodiment. As depicted, housing 600 includes a frame defined by front wall 605, sidewall 606, sidewall 608, and rear face 610. As depicted, the top edge of front wall 605 has a height which is lower than the top edge of rear face 610. Housing 600 may be configured to store one or more electronic devices 50, which may be mounted or resting within housing 600 in any suitable configuration for operation.

As depicted, the surface of upper face 612 is sloped from the top edge of front wall 605 to a point along top surface 620 which has a higher height than the top edge of front wall 605. In some embodiments, top surface 620 is substantially horizontal and extends from the top edge of rear face 610 for a portion of side walls 606, 608. In some embodiments, top surface 620 is not horizontal and may be sloped. In some embodiments, upper face 612 may extend the entire length from front wall 605 to rear face 610.

In some embodiments, top surface 620 includes an outlet 622 which allows evaporated cooling liquid 304 gas bubbles to pass therethrough. In some embodiments, outlet 622 may extend the entire length from sidewall 606 to sidewall 608. In some embodiments, outlet 622 may extend through only a portion of the length from sidewall 606 to 608. It will be appreciated that top surface 620 may be flat, but may also include features adjacent to cavity 622 which facilitate the movement of gas bubbles 304 up and through cavity 622. Moreover, in some embodiments there may be more than one outlet 622 on top surface 620. In some embodiments, there might not be an outlet 622 on top surface 620, and cooling liquid vapor 304 may escape from housing 600 instead via rear cavities 650.

In some embodiments, top wall 630 extends upward from top surface 620 and/or upper face 612 of housing 600. In some embodiments, top wall 630 is substantially vertical in orientation. In some embodiments, top wall 630 may be at an angle to the vertical axis. In some embodiments, top wall 630 of housing 600 and lip 155 of tank 100 are configured so as to be aligned when housing 600 is resting along floor 110 of tank 100 and is laterally pressed against lip 155 of tank 100. In some embodiments, the combination of lip 155 pressed against top wall 630 creates a seal. In some embodiments, the seal may be impermeable to gas or otherwise prevent the passage of gas bubbles 304 through any space between top wall 630 and lip 155. In this manner, some embodiments are operable to cause substantially all cooling liquid vapour 304 to enter vapor zone 151.

In some embodiments, a flexible seal 624 may be disposed in the vicinity of the interface between top wall 630 and the surface from which top wall 630 emanates (e.g. top surface 620 and/or upper face 612). In some embodiments, flexible seal 624 is a rubberized seal configured to deform to adapt to the shape of lip 155. In some embodiments, flexible seal comprises one or more fins configured to further impede the flow of gas bubbles between lip 155 and top surface 620 and/or top wall 630. As depicted in the figures, flexible seal 624 may be disposed on both of top wall 630 and top surface 620. In some embodiments, flexible seal 624 may be disposed on one of top wall 630 and top surface 620.

In some embodiments, when electronic devices 50 are in operation and immersed in cooling liquid 300, some of the cooling liquid 300 may evaporate as the temperature of the hardware components of electronic devices exceeds the boiling point of the cooling liquid 300. In some embodiments, the sloping of upper face 612 (from lower on the front wall 605 to higher at the top wall 630) may bias evaporated cooling liquid gas bubbles 304 to move towards outlet 622 (depicted as direction A in FIG. 4).

This is due to the fact that bubbles in a liquid solution tend to move vertically upward.

Therefore, when the fluid level 302 is higher than the height of the lower end 170 of lip 155, the upper face 612 and/or top surface 620 of housing 600 is completely submerged in cooling liquid 300, and therefore evaporated cooling liquid bubbles 304 will migrate to the highest vertical point possible within cooling liquid 300.

Thus, in some embodiments, all or substantially all of the evaporated cooling liquid vapor 304 will travel along path A and exit housing 600 at outlet 622. In some embodiments, the gas bubbles 304 exit cooling liquid 300 and enter vapor zone 151 of upper portion 150 of tank 100. As a corollary, in some embodiments, no or substantially no evaporated cooling liquid vapor is able to exit housing 600 and into the front portion 140 of tank 100. This may provide a significant benefit over existing systems in that front portion 140 may be accessed to add and remove electronic devices 50 and housings 600 without cooling liquid vapor escaping in the process. This is beneficial for a multitude of reasons.

First, cooling liquid 300 is extremely expensive (for example, 3M Novec 7100 cooling liquid currently costs around $600-$700 per gallon) and any cooling liquid vapor 304 which is lost from the system will ultimately have to be replaced in tank 100 at great expense. Second, the absence of cooling liquid vapor 304 in front portion 140 (aside from within housing 600, which is sealed and cannot escape from housing 600 into front portion 140) obviates any need for lid 125 to be air tight, which may significantly reduce the design complexity of the overall system. Moreover, when electronic devices 50 are added to or removed from tank 100, this can be easily accomplished by simply lifting lid 125 without any losses of cooling liquid vapor. In prior systems, losses of cooling liquid during opening and closing of two-phase immersion cooling systems represented a significant source of operating expense. Moreover, in prior systems, lids and other means for accessing the electronic devices 50 within a two-phase immersion cooling system had to be air tight in order to prevent cooling liquid vapor 304 from escaping during regular operation.

An additional benefit associated with some embodiments of the present invention is the recognition that the two-phase immersion cooling systems typically require complicated bellows systems for handling changes in air pressure, particularly because certain cooling liquids (e.g. 3M Novec) contain dissolved oxygen which escapes during evaporation. This results in oxygen gas building up within the tank, which must be dealt with in some manner). Contrastingly, the systems and methods described herein allow for all or substantially all of the cooling liquid vapor 304 (and any oxygen gas release during evaporation) to flow through vapor zone 151 and out of vapor outlet 153. From here, released oxygen gas may be processed or treated in any manner desired without impacting the operation of tank 100 or housing 600, thereby greatly simplifying the design of the two-phase cooling system.

In some embodiments, after cooling liquid vapor 304 has been treated by a downstream heat exchange system, the condensed cooling liquid 304′ will not have regained the same amount of dissolved oxygen that was released during the first instance of the cooling liquid 300 evaporating. As such, some embodiments of the two-phase immersion cooling system described herein may reach a steady state of operation in which the cooling liquid 300 present in tank 100 has released the majority of its dissolved oxygen after one or more evaporation and condensation cycles.

Therefore, in some embodiments the management of released oxygen gas is necessary only during an initial stage of operation and might not be an ongoing operational constraint. This may further simplify the design complexity of embodiments of the two-phase immersion cooling system described herein relative to prior two-phase immersion cooling systems which require active treatment of released oxygen gas and/or periodic adding of new cooling liquid 300 to compensate for cooling liquid which has been lost (e.g. by vapor escaping from the system).

In some embodiments, the two-phase immersion cooling system may be a substantially closed loop design. That is, cooling liquid 300 may be converted to cooling liquid vapor 304, and subsequently condensed to cooling liquid 304′ which is then re-circulated into tank 100. Thus, in some embodiments there might not be a need for cooling liquid 300 to be added to tank 100 to “top up” the cooling liquid level to compensate for cooling liquid 300 which has been lost to the outside environment. This may represent a substantial operational cost saving relative to known two-phase immersion cooling systems, in which cooling liquid vapor 304 is routinely and regularly lost to the outside environment when, for example, the interior of the system is accessed to add or remove electronic devices 50.

In some embodiments, the two-phase immersion cooling system disclosed herein may be more simple for operators to use relative to known systems. For example, an operator or technician would be responsible for adding and removing housings 600 from tank 100, but need not (and may not be) aware that they are using a two-phase immersion cooling system because all of the processes involving phase changes, gas bubbles, and condensation are occurring behind lip 155 and thus out of view from the operator. Thus, operators may require relatively less special training in order to learn and operate some embodiments of the two-phase immersion cooling system described herein when compared to known two-phase immersion cooling systems.

Moreover, it is expected that when an operator intends on removing a housing 600 from tank 100, the operator will first unplug the power source from housing 600. In some embodiments, it may only take a few seconds for cooling liquid 300 to reduce the operating temperature of electronic device 50 to below boiling temperatures once the electronic device 50 is powered down. Therefore, in some embodiments, there is an exceedingly low risk that a housing 600 being removed from tank 100 would still be at a temperature sufficiently high to cause any residual cooling liquid 300 to evaporate. Therefore, there is relatively low risk that any cooling liquid vapor 304 might escape from housing 600 while housing 600 is being moved away from lip 155 (as the temperature will have already fallen sufficient to prevent any further evaporation from occurring within housing 600).

It will be appreciated that the fill line 302 of cooling liquid 300 will vary as housings 600 are added and/or removed. In some embodiments, tank 100 may contain a minimum fill line denoted on an interior surface of the tank 100 so as to warn operators and technicians that additional housings 600 should not be removed from tank 100 unless a) additional housings 600 and/or electronic devices 50 are added to tank 100 prior to removal, b) additional cooling liquid 300 is added to tank 100, c) the volume of the removed housings 600/devices 50 is replaced by another object (e.g. a block or any other object with a purpose of occupying space within tank 100) or d) all electronic devices 50 are powered down and no further boiling of cooling liquid 300 is occurring.

Although the figures depict top surface 620 as being horizontal, it is contemplated that in other embodiments, top surface 620 may take on any suitable orientation provided top wall 630 and lip 155 are configured to form a seal to prevent cooling liquid vapors from escaping into first portion 140 via spaces between lip 155 and top wall 630.

As depicted in FIGS. 6B and 7A, rear face 610 of housing 600 may include one or more ribs 640 and one or more cavities 650. Ribs 640 may provide some structural strength to housing 600 so as to prevent deformation under the weight of electronic devices 50 contained therein. Cavities 650 may facilitate and/or enable circulation of cooling liquid 300 throughout the interior of housing 600. In some embodiments, cooling liquid 300 may circulate primarily through convection currents (that is, through lower temperature cooling liquid 300 sinking, and higher temperature cooling liquid rising and potentially evaporating when in contact with hot components).

Cavities 650 may further serve as spaces for accessing the electronic devices 50 contained within housing 600 (for example, for plugging and unplugging power cables and/or other cables, as well as adding or removing printed circuit boards or other electronic components).

In some embodiments, housing 600 may have an open underside so as to further facilitate circulation of cooling liquid 300. In some embodiments, one or more of sidewalls 606 and 608 may include one or more respective sidewall cavities 666, 668.

As depicted in FIGS. 7A and 7B, sidewall cavities 666, 668 may be located towards the base of housing 600. It is contemplated that in other embodiments, sidewall cavities may be contained at any location along sidewalls 606, 608 (provided such sidewall cavities do not provide a route for cooling vapor bubbles 304 to escape into front portion 140). Moreover, sidewall cavities 666, 668 may vary in length, in some embodiments extending substantially the entire length from front wall 605 to rear face 610, and in other embodiments extending less than the entire length from front wall 605 to rear face 610.

In some embodiments, housing 600 may include brackets 686, 688 extending from upper face 612. In some embodiments, brackets 686, 688 may be attached to top wall 630. In some embodiments, top wall 630 may be mechanically separate from brackets 686, 688. As depicted, grip 680 may extend between brackets 686, 688 and may provide a convenient means for users to lift and otherwise move or displace housing 600.

As depicted, grip 680 extends between the left and right brackets 686, 688 of housing 600 to allow housing 600 to be handled or otherwise manipulated by a user, e.g., to be lowered into a resting position within tank 100, pulled from its resting position within tank 100, or be pulled into a desired horizontal position along tank 100.

In some embodiments, grip 680 can be omitted, and housing 600 can be manipulated via another portion such as brackets 686, 688, or manually gripping the sidewalls of housing 600.

When housing 600 is in a resting position along floor 110 of tank 100, a portion of each bracket 686, 688 may extend into cooling liquid 300 to immerse electronic device(s) 50 therein. Portions of housing 600 (e.g., grip 680 and portions of brackets 686, 688) may remain above the surface 302 of the cooling liquid 300. This facilitates easy manipulation of housing 600, e.g., to adjust its position without requiring a user to sink a hand into cooling liquid 300.

Various sizes and configurations of housing 600 may be provided. Housings 600 may differ from one another in width to accommodate electronic devices 50 of various widths. Housings 600 may also differ from one another in the length of their brackets 686, 688, to accommodate electronic devices 50 of various heights and to place such electronic devices 50 at various desired vertical positions within tank 100.

Larger sizes of housings 600 may include structural support members (e.g., additional ribs 640) to improve structural integrity when under mechanical load of mounted electronic devices 50.

Housings 600 may also differ from one another in the number of electronic devices 50 mountable thereto. For example, some housings 600 may be sized to accommodate a single electronic device 50. Meanwhile, some housings 600 may be sized to accommodate a greater number of devices, e.g., two electronic devices 50, or an even greater number of electronic devices 50. In some embodiments, where housings 600 are expected to be manually manipulable by a single user, the number of mountable electronic devices 50 may be constrained so that the overall size and mass of an individual housing 600 and mounted electronic devices 50 are within the ability of a single user to manipulate.

Each electronic device 50 may be one or more of a data storage device, a data processing device, a data networking device, another type of computing device, or any other type of electronic device that generates waste heat during operation. For example, electronic device 50 may be a cloud computing device, a web server, an image/video rendering server, a cryptocurrency mining device, or the like. In one specific example, cryptocurrency mining devices may include, for example, ASIC-based miners such as a Bitmain™ Antminer™ S19, or MicroBT™ Whatsminer™ M30S, or the like. Importantly, the flexible configuration of housing 600 disclosed herein allows tank 100 to accommodate a combination of different electronic devices 50, having different operating temperature requirements, and/or having different dimensions.

Electronic devices 50 may be wired for network access. Tank 100 may include suitable interfaces, ports, and openings, for network and/or power connections for electronic devices. For example, openings may be provided in a wall of tank 100 or via one of vapor outlet 153 or condensation inlet 154 to provide for passage of network and/or power connections (e.g. via a conduit). Such openings may include, for example, openings above a fill line 302 proximal to lid 125 (as shown in FIG. 8) to prevent interference between such network and/or power connections and a lid 125 placed over tank 100. In some embodiments, tank 100 may include a plurality of network and/or power connections 800 above fluid level 302. As depicted in FIG. 8, a rail may be disposed across the tank 100 and act as a power distribution unit (PDU) with power outlets configured to accept electrical cables from electronic devices 50 located in housings 600 and tank 100.

In some embodiments, the dimensions of housing 600 and tank 100 may be as small as reasonably required to accommodate the dimensions of the specific electronic devices 50 being used/cooled within tank 100. This may be for a multitude of reasons, including that the cooling liquid 300 is so expensive that minimizing the amount of cooling fluid 300 used may be advantageous, and a smaller tank 100 size may contribute to a smaller footprint for tank 100. In some embodiments, the housing 600 and tank 100 dimensions may be only slightly larger than the length, width and/or height dimensions of electronic devices 50. In some embodiments, electronic devices 50 may range from 12 to 40 inches long, and from 2 to 21 inches wide.

Tank 100 is formed of metals (e.g., stainless steel, aluminum, or the like) and/or other materials (e.g., plastics, resins, or the like) having suitable strength and stiffness to support the mechanical load of both cooling liquid 300 and electronic devices 50. Tank 100 is formed of materials (or materials having suitable coatings, such as anodized aluminum) to resist corrosion, damage, or otherwise undesirable effects caused by interactions between the tank material and cooling liquid 300. Housings 600 may also be formed of similar materials to tank 100.

In some embodiments, cooling liquid 300 is a conventional dielectric liquid such as 3M™ Novec™ dielectric liquid. In some embodiments, another liquid that is thermally conductive yet electrically substantially non-conductive may be used. In some embodiments, the cooling liquid is non-flammable. In some embodiments, a glycol such as ethylene glycol or propylene glycol, or a solution thereof, may be used. In some embodiments, a polyalphaolefin or similar synthetic oil may be used. In various embodiments, various suitable synthetic or natural hydrocarbons, or combinations thereof may be used. In some embodiments, deionized water may be used.

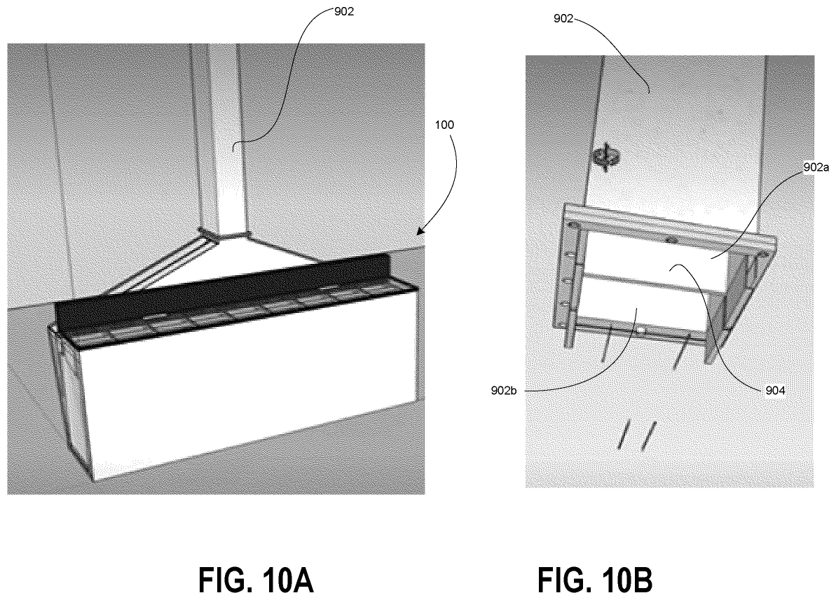

FIG. 10A depicts a perspective view of an example cooling system which includes a heat exchange system 900. As depicted, a conduit 902 seals vapor outlet 153 and condensation inlet 154, such that any cooling vapor 304 and condensed cooling liquid 304′ remain contained within the system. As depicted in FIG. 10B, a barrier 904 prevents the mixing of vapor 304 and condensed liquid 304′. In some embodiments, barrier 904 may be impermeable. Cooling vapor 304 may travel upward through conduit channel 902a. Condensed cooling liquid 304′ may fall vertically downward through conduit channel 902b. In some embodiments, conduit 902 may terminate with a cooling unit 910.

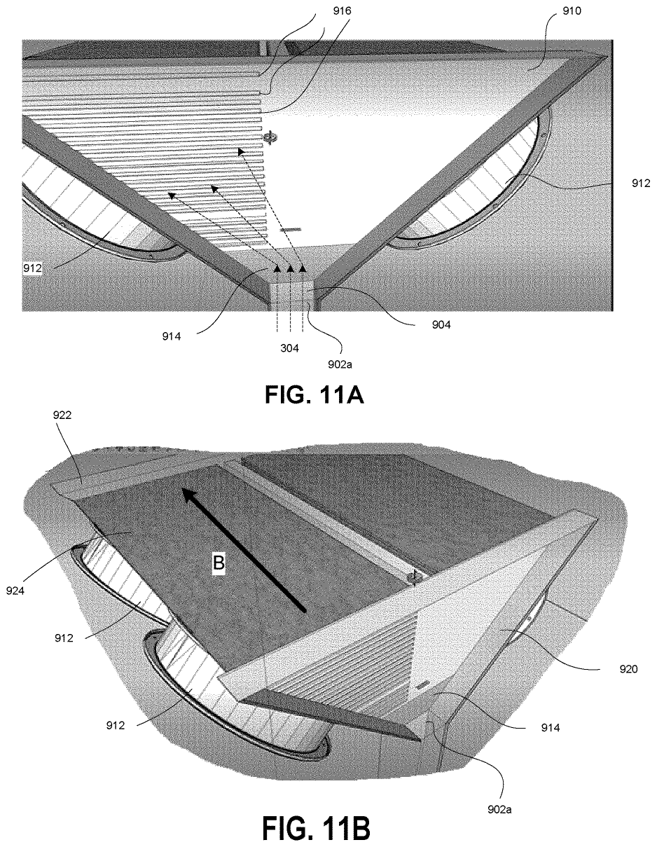

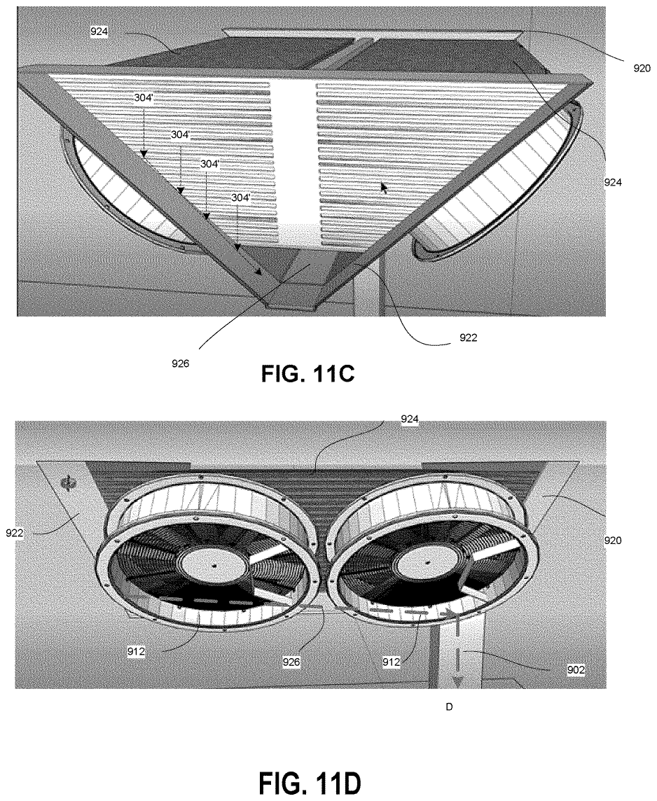

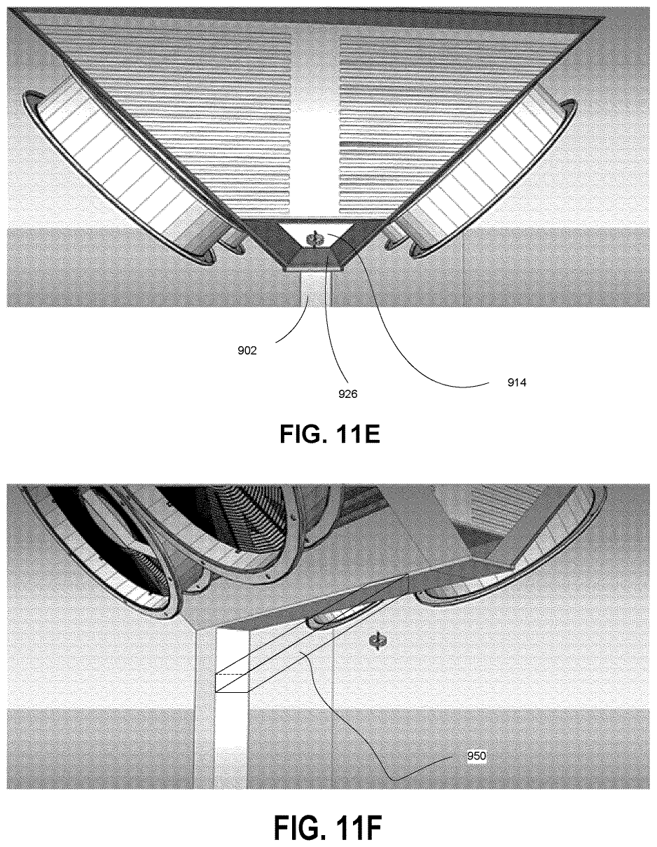

FIG. 11A is a simplified perspective view of an example cooling unit 910. As depicted, housing 910 includes a dividing wall 914, one or more tubes 918, one or more cooling fins 924, and one or more fans 912. In some embodiments, dividing wall 914 divides a lower portion of housing 910 as a continuation of conduit barrier 904, such that cooling vapor 304 and condensed liquid 304′ cannot mix. In some embodiments, openings 918 may be located at a height which is vertically higher than dividing wall 914. In some embodiments, tubes 918 may be made of copper. In some embodiments, housing 910 may be located in an environment which has exposure and/or access to ambient air. For example, housing 910 may be located exterior to a building (e.g. on a roof or on a side of a building).

During operation, cooling vapor 304 may enter housing 910 via conduit channel 902a, and disperse throughout the volume of the front portion 20 of housing 910, including entering tubes 918. In some embodiments, cooling vapor 304 may travel in direction C (FIG. 11B) through tubes 918 towards rear portion 922. As vapor 304 travels across tubes 918, fans 912 may blow air towards tubes 918. In some embodiments, vapor 304 may have a temperature of about 62-65 degrees Celsius. In some embodiments, air pumped by fan(s) 912 may have a lower temperature than vapor 304. In some embodiments, the air pumped by fan(s) 912 may be blown from an outside environment, and thereby may be expected to have a lower temperature than vapor 304. As the cooler air blown by fan(s) 912 contacts tubes 918 and/or cooling fins 924, heat may be removed from vapor 304. As the temperature of vapor 304 drops, vapor 304 may fall below its boiling point and condense into condensed liquid 304′. As noted above, the boiling point of cooling liquid 300 may be greater than 50 degrees Celsius. Typically, the ambient air temperature in the hottest areas of the world does not exceed the boiling point of cooling liquid 300 and therefore may be sufficient to condense vapor 304 into condensed cooling liquid 304′ without the use of refrigerants, compressors, and the like.

As depicted in FIGS. 11A and 11B, fans 912 may blow air towards cooling fins 924 and tubes 918 at an angle which is less than 180 degrees. That is, air blowing from fans 912 may contact fins 924 and/or tubes 918, rather than blowing parallel to fins 924 and/or tubes 918. In other embodiments, fans 912 may be arranged so as to blow air parallel to fins 924 and/or tubes 918. In some embodiments, arrangements in which fans 912 blow air in a non-parallel manner may effect heat transfer more efficiently than configurations in which air is blown parallel to fins 924 and/or tubes 918.

FIG. 11C is a perspective view of cooling unit 910 facing towards rear portion 922. It will be appreciated that as heat exchange system 900 is a closed system, rear portion 922 is sealed (e.g. by a panel which is not shown in FIG. 11C). Such a panel is removed from FIG. 11C for greater simplicity in describing the interior features of cooling unit 910. As depicted, as vapor 304 travels in direction A towards rear portion 922, vapor 304 condenses into condensed liquid 304′. Condensed liquid 304′ may then descend due to gravity in and around collection basin 926. In some embodiments, tubes 918 may be oriented at an angle to the horizontal, such that the height of a tube 918 at the front portion 920 is higher than the height of tube 918 at rear portion 922. Such an angle may facilitate condensed liquid 304′ travelling towards rear portion 922 once condensed. In some embodiments, tubes 918 may be substantially horizontal. In some embodiments, tubes 918 may be dimensioned such that capillary action may act on condensed liquid 304′ to facilitate travelling towards rear portion 922.

FIG. 11D is a side perspective view of cooling unit 910. As depicted, as condensed liquid 304′ travels towards collection basin 926, the condensed liquid travels along direction B until reaching conduit channel 902b and dividing wall 914. When condensed liquid 304′ reaches conduit channel 902b, the condensed liquid 304′ may then fall due to gravity and re-enter tank 100 via condensation inlet 154, where gravity will cause the condensed cooling liquid 304′ to fall down through condensation return zone 152 and between barrier 160 and rear wall 104. In some embodiments, condensed cooling liquid 304′ may be lower in temperature than the average temperature of the cooling liquid 300, and therefore may continue to sink past the lower end of barrier 160 via convection currents, resulting in re-circulation. It will be appreciated that in instances in which a high amount of condensed liquid 304′ is being produced, dividing wall 914 divides conduit channel 902b from conduit channel 902a, thereby preventing any condensed liquid 304′ from entering conduit channel 902a and mixing with vapor 304.

In some embodiments, collection basin 926 may be oriented so as to bias the direction of travel of condensed liquid 304′ towards conduit channel 902b and condensation return zone 152. For example, collection basin 926 may have a height at rear portion 922 which is higher than a height of collection basin 926 at front portion 920. In some embodiments, collection basin 926 may be a flat surface. In some embodiments, collection basin may be a curved surface which further biases condensed liquid 304′ to travel towards conduit channel 902b and condensation return zone 152. In some embodiments, a bypass 950 may connect from a location along collection basin 926 and connect to conduit channel 902b. An example configuration is depicted in FIG. 11F, in which bypass 950 diverts condensed cooling liquid 304′ from collection basin 926 to conduit channel 902b. It is contemplated that virtually any shape of bypass 950 may be used provided condensed liquid 304′ is routed back to conduit channel 902b.

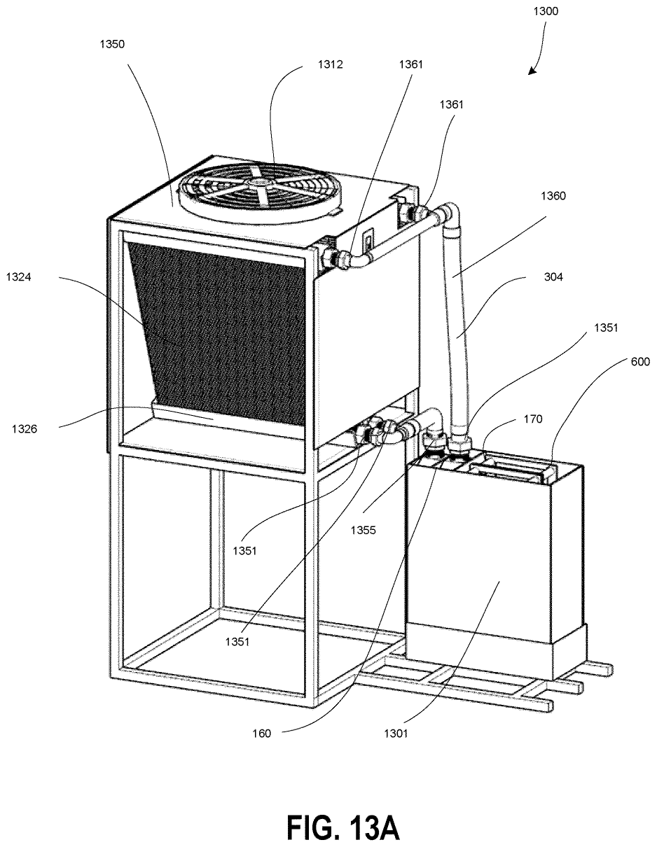

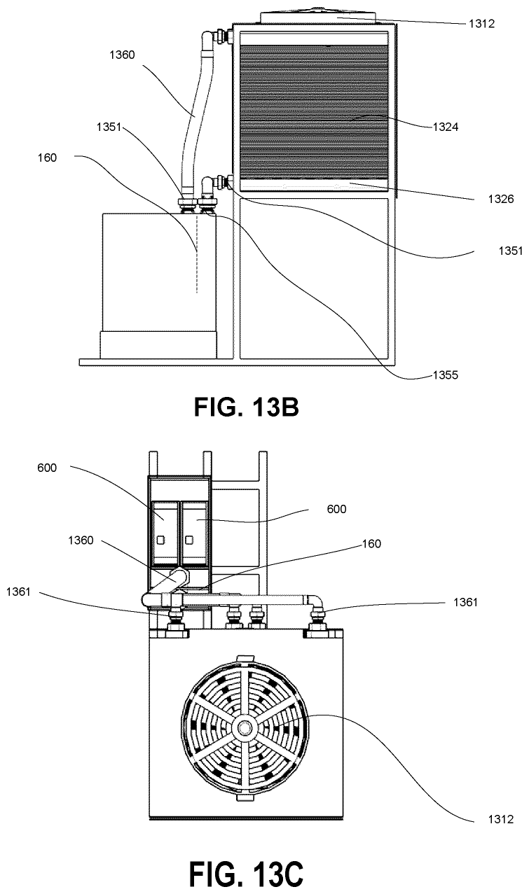

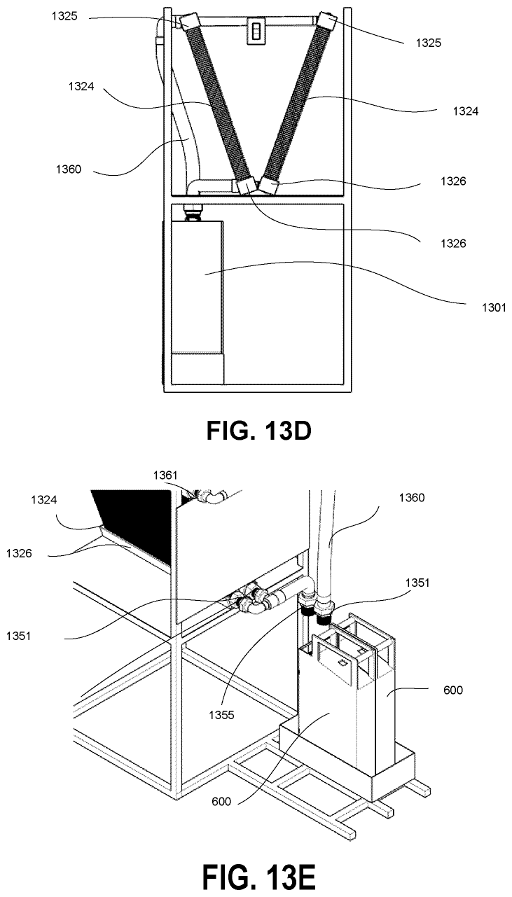

Although FIGS. 11A and 11B depict cooling unit 910 having a cross-section which is triangular in shape, this is merely an example and other configurations which are shapes other than triangles may be used. For example, cooling unit 910, 1350 may have a rectangular cross-section, as depicted in FIG. 13F. In some embodiments, cooling fins 924 may be made of copper or any other suitable material which has a suitable level of thermal conductivity for effecting heat transfer from vapor 304 to achieve condensation.

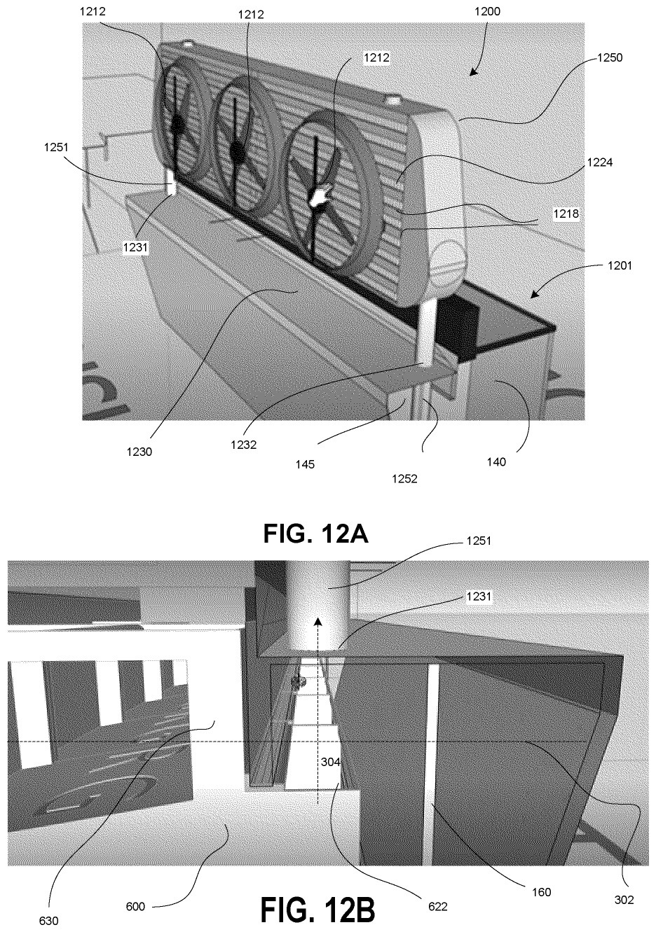

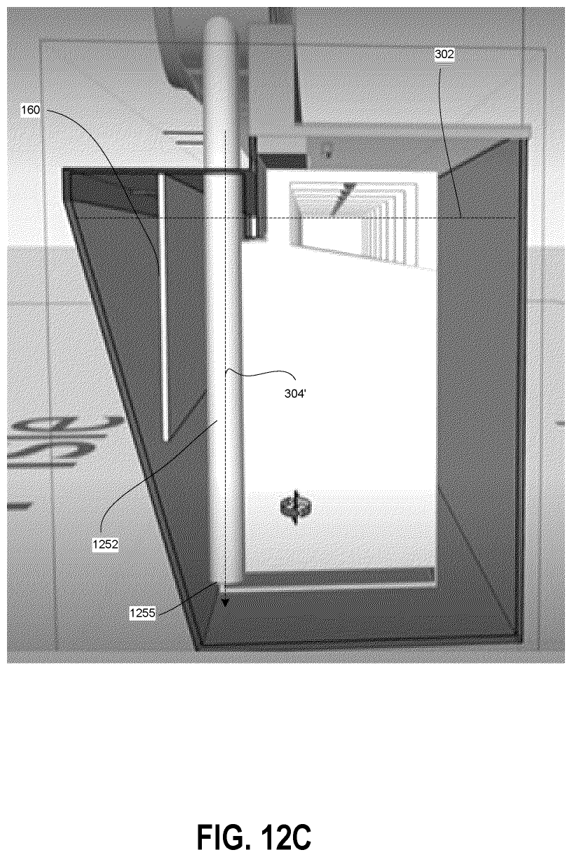

FIG. 12A depicts still another example embodiment of a heat exchange system 1200, in accordance with some embodiments. Referring back to FIG. 1B, which is a top view of a tank 100, it is common in data center applications for to manage the air flow in a manner which includes a cold aisle 1210 and a hot aisle 1220. The goal of a hot/cold aisle configuration may be to manage airflow in a way which conserves energy and lowers cooling costs. Cold aisle 1210 may include, for example, air conditioned air which is suitable for entering into cold air intakes for conventional heat management systems. Hot aisle 1220 may include hot air exhausts from computing systems, and may face air conditioning return ducts. A containment system may isolate hot aisles 1220 from cold aisles 1210 so as to prevent hot and cold air from mixing (which mixing would reduce the efficiency of such systems). However, the use of immersion cooling systems may be difficult with existing hot/cold aisle systems. For example, conventional immersion cooling systems may result in frequent spillage of coolant, as well as coolant vapor condensing within the cold aisle 1210 (e.g. as computing devices are added or removed from a tank).

In some embodiments, system 1200 which may be compatible with existing hot/cold aisle systems. Moreover, system 1200 may be of particular utility in situations in which an exterior heat exchange system (such as system 900) may be undesirable to implement (e.g. in situations where the a large scale heat exchange system which extends to the exterior of a building may be inappropriate, unnecessary, or too costly).

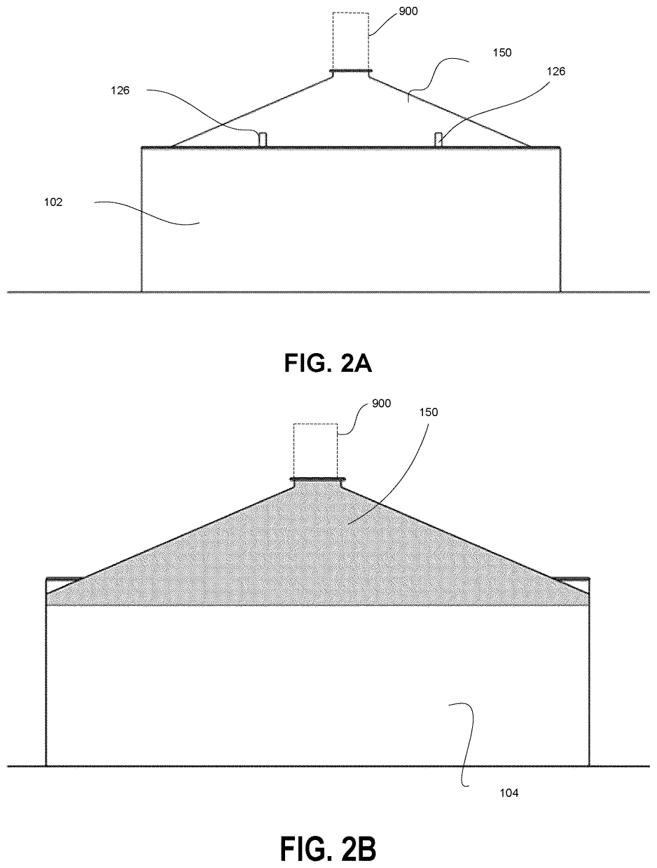

As depicted, system 1200 may include a tank 1201 which is similar in many respects to tank 100 depicted in FIGS. 1-8. In some embodiments, tank 1201 may include front portion 140 and rear portion 145 separated by lip 170, and side walls 106, 108, while upper portion 150 may be omitted and/or replaced by rear lid 1230. Although omitted from FIG. 12A for ease of reference, tank 1201 may include side wall 108 to provide a seal to contain cooling liquid 300 within the reservoir of tank 1201. In some embodiments, rear lid 1230 may include first aperture 1231 and second aperture 1232.

In some embodiments, cooling unit 1250 may be coupled to tank 1201 via the first and second apertures 1231, 1232 in rear lid 1230. As depicted, cooling unit 1251 may include vapor inlet 1251, condensation return outlet 1252, one or more tubes 1256, one or more cooling fins 1258, and one or more fans 1212 configured to blow air from cold aisle 1210 to hot aisle 1220.

FIG. 12B is a depiction of an interior of system 1200. As depicted, vapor inlet 1251 forms a seal with aperture 1231. During operation, vapor 304 rises through rear portion 145 of tank 1201 and into vapor inlet 1251. In some embodiments, vapor inlet 1251 is coupled to a plurality of tubes 1218. In some embodiments, tubes 1218 extend to a terminal side which drains into condensation return outlet 1252. In some embodiments, tubes 1218 may be slanted towards condensation return outlet 1252 so as to facilitate transport of condensed cooling liquid 304′ towards condensation return outlet 1252.

During operation, vapor 304 rises through vapor inlet 1251 and disperses throughout one or more tubes 1218. In some embodiments, the pressure caused by accumulating vapor 304 bubbles may be sufficient to force vapor 304 to travel across tubes 1218 towards condensation return outlet 1252. In some embodiments, fans 1212 may be configured to suck and/or blow air across tubes 1218 and/or cooling fins 1224. In so doing, heat energy may be transferred away from vapor 304, thereby causing vapor 304 to condense into condensed cooling liquid 304′. In some embodiments, fans 1212 may be configured to blow air from cold aisle 1210 across cooling unit 1250 and towards hot aisle 1220. In this manner, existing data centers (or rooms more generally) which have been configured for a hot/cold aisle airflow management system may be adapted easily to the use of system 1200.

FIG. 12C is a depiction of an interior of system 1200 facing side wall 108 (not pictured). As depicted, condensation return outlet 1252 forms a seal with aperture 1232 and extends downward into rear portion 145 of tank 1201, with condensed cooling liquid 304′ exiting into tank 1201 via exit port 1255. In some embodiments, exit port 1255 of return outlet 1252 extends vertically downward to a height which is lower than any source of vapor 304 bubbles from any of housings 600 within tank 1201. In this manner, no vapor 304 can enter condensation outlet 1252, as vapor bubbles which are below the cooling liquid level 302 in tank 1201 can only move upward. In some embodiments, condensation outlet 1252 may be positioned at a point along length L which is closer to a sidewall 106, 108. In this manner, the likelihood of any bubbles entering condensation outlet 1252 will be minimal even when the exit port 1255 of condensation outlet 1252 is located at a height above a source of vapor from one of housings 600. In this manner, it is contemplated that in some embodiments, condensation outlet 1252 may have an exit port 1255 which may to be located vertically above the lowest source of vapor 304 bubbles in tank 1201 without vapor 304 bubbles entering exit port 1255 and mixing with condensed liquid 304′.

FIG. 13A depicts a perspective view of still another example immersion cooling system 1300, in accordance with some embodiments. FIG. 13B is a side view of system 1300. FIG. 13C is a top view of system 1300. As depicted, one or more housings 600 containing one or more electronic devices 50 may be submerged in cooling liquid 300 within tank 1301. In some embodiments, tank 1301 may be similar to tank 100 in that tank 1301 maintains a fluid-tight seal to prevent cooling liquid 300 from escaping, and includes a front portion 140 and a rear portion 145 divided by lip 170.

Vapor 304 generated as cooling liquid 300 is heated by electronic devices 50 may then rise through rear portion 145 and enter vapor inlet 1351. In some embodiments, barrier 160 prevents vapor 304 bubbles from reaching exit port 1355. As depicted in FIG. 13E (which depicts system 1300 with the casing of tank 1301 removed), there are two housings 600, both of which may be generating vapor 304 which migrates into vapor inlet 1351. In other embodiments, fewer than two housings 600, or more than two housings 600 may be placed within tank 1301.

Vapor 304 then travels through vapor channel 1360 until reaching vapor channel exits 1361. As depicted, vapor channel 1360 splits into two vapor channel exits 1361. It is contemplated that other embodiments may include fewer than two, or more than two vapor channel exits 1361. As depicted, vapor 304 travels from vapor channel exit(s) 1361 into header(s) 1325. Upon entering header(s) 1325, vapor 304 may disperse and traverse longitudinally as well as downward towards collection basin(s) 1326. In some embodiments, a series of one or more tubes may trace a path from header 1325 to collection basin 1326. In some embodiments, such a path may include straight lines. In other embodiments, tubes may take a path having any suitably shaped configuration (e.g. zig-zags, switchback patterns, or the like). As vapor 304 travels through the tubes, fan 1312 may be configured to blow air which contacts cooling fins 1324 and/or the tubes and extracts heat energy from vapor 304. As vapor 304 travels towards collection basin 1326, vapor 304 may condense into condensed liquid 304′ upon reaching a temperature which is below the boiling point of cooling liquid 300. In this sense, header 1325, cooling fins 1324 and collection basin 1326 may be conceptualized together as a radiator through which vapor 304 travels and loses heat energy.

When vapor 304 has condensed to condensed liquid 304′ gravity may cause condensed liquid 304′ to fall into collection basin 1326. In some embodiments, collection basin may be biased (e.g. slanted from a first end further away from tank 1301 to a second end closer to tank 1301 than the first end) so as to cause condensed liquid 304′ to flow into condensation outlet(s) 1351 and eventually to exit port 1355, thus returning to tank 1301 behind barrier 160. As with certain other embodiments described herein, system 1300 may be a closed system in which substantially no quantity of vapor 304 may escape during the condensation process in cooling unit 1350. As depicted in FIG. 13A, it may be possible to operate a closed system even when tank 1301 includes an opening at the top of front portion 140 (i.e. omits lid 125). This may be possible due to the nature of housing 600 diverting all vapor 304 bubbles beyond lip 170 and into rear portion 145, thereby preventing vapor 304 bubbles from escaping from an opening in front portion 140. As such, there may be significant cost savings by conserving the volume of cooling liquid 300 which is used during operation of system 1300.

FIG. 13D is a rear view of system 1300, with the panels of cooling unit 1350 removed for simplicity. As depicted, vapor channel 1360 may feed two individual radiators (e.g. 2 separate sets of header 1325, cooling fins 1324, and collection basin 1326), and each respective collection basin 1326 may join a communal return line via condensation outlet 1351 which terminates in exit port 1355. Although the figures depict system 1300 having two radiator units within cooling unit 1350, it is contemplated that other embodiments may include fewer than two radiator units, or more than two radiator units as desired. Moreover, although FIG. 13D depicts cooling fins 1324 oriented at an angle to the vertical, other embodiments may include cooling fins 1324 which are oriented substantially vertically. In some embodiments, configurations in which the air blown from fan 1312 impacts cooling fins 1324 at an angle (as opposed to running parallel to cooling fins 1324) may transfer heat energy from cooling fins 1324 (and therefore from vapor 304) with greater efficiency.

Various embodiments described herein may offer the benefit over traditional cooling systems of obviating the need for compressors and/or pumps. For example, cooling liquid vapor 304 may be transported via conduit 902 to heat exchange system 900 without the use of any pumps. Similarly, vapor 304 may be transported via vapor inlet 1251 to cooling unit 1250 without the use of any pumps. Likewise, while present within heat exchange system 900 or cooling unit 1250, vapor 304 may be condensed into condensed liquid 304′ and returned to the tank 100, 1201 without the use of any pumps. As such, some embodiments described herein may offer advantages including reduced energy consumption and a less complex mechanical design than conventional cooling systems. Rather than use pumps and/or compressors to effect changes in volume and/or air pressure to achieve changes in temperature, some embodiments of the systems described herein may achieve the extraction of heat from electronic devices 50 via the vaporization of cooling liquid 300 and condensation of vaporized cooling liquid 304 without a change in pressure or the use of complex mechanical configurations. Instead, the energy to vaporize cooling liquid 300 may be provided by the waste heat generated by electronic devices 50, which would be producing waste heat in any event during operation. As such, the systems and methods described herein may make use of waste heat generated by electronic devices 50 to operate some or all of the heat exchange systems and cooling units described herein to provide the necessary cooling for electronic devices 50. In some embodiments, these systems are closed-loop systems, which implies that minimal or no volume of cooling liquid 300 is lost from the system during the cycle of vaporization and condensation. As such, significant cost savings may be achieved relative to conventional immersion cooling systems.

Of course, the above described embodiments are intended to be illustrative only and in no way limiting. The described embodiments are susceptible to many modifications of form, arrangement of parts, details and order of operation. The disclosure is intended to encompass all such modification within its scope, as defined by the claims.

What is claimed is:

1. An immersion cooling system for electronic devices, the system comprising:
a tank including:
a front portion having an opening for receiving a cooling liquid;
a rear portion in fluid communication with said front portion;
a lip extending downward from an upper surface of said front portion into said tank;
one or more housings, each of said housings containing an electronic device to be immersed in the cooling liquid, each of the housings including:
a front face having a top end at a first height;
first and second sidewalls extending from said front face;
a top surface having a second height higher than said first height and extending from said first sidewall to said second sidewall;
a top wall protruding from said top surface and extending from said first sidewall to said second sidewall; and
an interface between said top surface and said top wall, said interface forming a seal with said lip of said tank to prevent movement of evaporated cooling liquid from said rear portion to said front portion.

2. The system of claim 1, wherein said tank comprises an upper tank portion comprising a vapor zone for receiving said evaporated cooling liquid and routing said evaporated cooling liquid to a vapor outlet at a distal end of said vapor zone.

3. The system of claim 2, wherein upper tank portion comprises a condensation return zone in fluid communication with said rear portion, said condensation return zone having a condensation return inlet at a distal end thereof.

4. The system of claim 3, wherein said upper tank portion comprises a barrier dividing said upper tank portion into said vapor zone and said condensation return zone.

5. The system of claim 4, wherein said barrier extends from said upper tank portion into said rear tank portion.

6. The system of claim 3, wherein said condensation return zone comprises one or more panels for directing condensed cooling liquid.

7. The system of claim 1, wherein a height of a lower end of said lip is lower than a fill level of said cooling liquid in said front portion.

8. The system of claim 4, wherein said barrier extends from a first tank sidewall to a second tank sidewall.

9. The system of claim 1, further comprising a removable lid for covering said opening of said front portion.

10. The system of claim 1, further comprising a power connector configured to power said electronic devices.

11. The system of claim 1, wherein each of said housings includes a grip for removing said housing from said front portion of said tank.

12. The system of claim 9, wherein said removable lid forms a permeable seal with said front portion of said tank.

13. The system of claim 1, wherein said top surface comprises an outlet disposed therein.

14. A housing for an electronic device in an immersion cooling tank, the housing comprising:
a front face having a top end at a first height;
first and second sidewalls extending from said front face;
a top surface having a second height higher than said first height and extending from said first sidewall to said second sidewall;
an upper face connecting said top surface to said front face, said upper face extending from said first sidewall to said second sidewall;
a top wall protruding from said top surface and extending from said first sidewall to said second sidewall; and
an interface between said top surface and said top wall, said interface being configured to form a seal with a lip of said immersion cooling tank to prevent movement of evaporated cooling fluid from entering an area between said lip and said top wall.

15. The housing of claim 14, wherein said seal comprises a flexible material.

16. The housing of claim 14, further comprising one or more sidewall cavities disposed in at least one of said sidewalls and below said electronic device.

17. The housing of claim 14, further comprising a back face having one or more ribs and one or more cavities.

18. The housing of claim 14, further comprising a plurality of brackets extending from said upper face.

19. The housing of claim 18, further comprising a grip extending between said brackets.

20. The housing of claim 14, wherein said upper face is a flat surface.

21. The housing of claim 14, further comprising a bracket for removably mounting the electronic device.

22. A tank for immersion cooling of electronic devices contained in a housing, the tank comprising:
a front wall and a rear wall connected by first and second side walls;
a front portion having an opening for receiving a cooling liquid;
a rear portion in fluid communication with said front portion;
a lip extending downward from an upper surface of said front portion into said tank, said lip configured to form a seal with said housing;
wherein the cooling liquid evaporates and travels to the rear portion, and wherein the electronic devices are immersable in said cooling liquid.

23. The tank of claim 22, further comprising an upper portion comprising a vapor zone for receiving said evaporated cooling liquid and routing said evaporated cooling liquid to a vapor outlet at a distal end of said vapor zone.

24. The tank of claim 23, wherein the upper tank portion comprises a condensation return zone having a condensation return inlet for receiving condensed cooling liquid and routing said condensed cooling liquid toward said rear wall.

25. The tank of claim 24, wherein said upper tank comprises a barrier dividing said upper tank portion into said vapor zone and said condensation return zone.

26. The tank of claim 25, wherein said barrier extends from said upper portion into said rear portion.

27. The tank of claim 24, wherein said condensation return zone comprises one or more panels for distributing condensed cooling liquid.

28. An immersion cooling system for electronic devices, the system comprising:
a tank as claimed in claim 22, and
a housing as claimed in claim 14,
wherein the housing and tank are arranged such that the lip of the tank forms a seal with the top wall of the housing.

29. An immersion cooling system for electronic devices, the system comprising:
a tank for receiving a cooling liquid, said tank comprising a vapor outlet and a condensation inlet;
one or more electronic devices immersed in the cooling liquid, wherein evaporated cooling liquid is directed to said vapor outlet; and
a cooling unit comprising:
a vapor input configured to receive said evaporated cooling liquid;
one or more tubes in fluid communication with said vapor input, said evaporated cooling liquid configured to circulate through said one or more tubes;
one or more fans configured to blow air towards said one or more tubes;
a condensation return channel fluidly coupled to said condensation inlet, said condensation return channel configured to receive a condensed cooling liquid,
wherein a pressure at said vapor outlet of said tank is substantially equal to a pressure within said one or more tubes.

30. The system of claim 29, wherein said cooling unit further comprises a collection basin configured to collect said condensed cooling liquid, and wherein said collection basin is further configured to transport said condensed cooling liquid to said condensation return channel.

31. The system of claim 29, wherein said one or more tubes are substantially horizontal.

32. The system of claim 29, wherein said tank portion comprises a barrier separating said vapor outlet from said condensation inlet.

33. The system of claim 29, wherein said vapor input of said cooling unit is positioned at a first height and wherein said condensation return channel is positioned at a second height lower than said first height.

34. The system of claim 29, wherein at least part of said cooling unit is positioned in an external environment.

35. The system of claim 29, wherein said cooling unit comprises one or more cooling fins thermally coupled to said one or more tubes.

36. The system of claim 35, wherein said one or more fans are configured to blow said air parallel to said cooling fins.

37. The system of claim 35, wherein said one or more fans are configured to blow said air at an angle greater than 0 degrees and less than 180 degrees to said cooling fins.

38. The system of claim 29, wherein said cooling unit has an air tight seal to an external environment.

39. The system of claim 29, wherein said vapor input is separated from said condensation return channel of said cooling unit.

40. The system of claim 29, wherein said tank comprises a lid having a first aperture connected to said vapor input and a second aperture connected to said condensation return channel.

41. The system of claim 29, wherein said condensation return channel extends below a level of said cooling liquid in said tank.

42. The system of claim 41, wherein an exit port of said condensation return channel is positioned at a first height, and wherein said one or more electronic devices are positioned at a second height greater than said first height.

43. The system of claim 29, wherein a front portion of said tank has an open top.

44. A cooling system for immersion cooling of electronic devices contained in a housing and stored in a tank, the cooling system comprising:
a vapor input configured to receive evaporated cooling liquid from said housing;
one or more tubes in fluid communication with said vapor input, said evaporated cooling liquid configured to circulate through said one or more tubes;
one or more fans configured to blow air towards said one or more tubes;
a condensation return channel configured to receive condensed cooling liquid and to dispense said condensed cooling to said tank;
wherein a pressure within said tank is substantially equal to a pressure within said one or more tubes.

45. The cooling system of claim 44, wherein all of said evaporated cooling liquid is condensed and returned to said tank.

46. The cooling system of claim 44, wherein said condensation return channel comprises an exit port, said exit port being positioned at a first height within said tank that is lower than a height of said electronic devices.

47. The cooling system of claim 44, wherein said vapor input is positioned at a first height within said tank that is higher than a height of said electronic devices.

48. The cooling system of claim 44, wherein said vapor input is positioned at a first height, and wherein said cooling system further comprises a collection basin positioned at a second height lower than said first height.

49. The method of claim 29, wherein said one or more electronic devices are housed within at least one housing.

50. The method of claim 49, wherein at least one of said housings is removable from said tank.
